(19) United States
(12) Patent Application Publication
(10) Pub. No.: US 2010/0193002 A1
(43) Pub. Date: Aug. 5, 2010

(54) SEMICONDUCTOR COMPONENT, METHOD FOR THE PRODUCTION THEREOF, AND USE THEREOF

(75) Inventors: Frank Dimroth, Freiburg (DE); Jara Fernandez, Freiburg (DE); Stefan Janz, Freiburg (DE)

Correspondence Address: MARSHALL & MELHORN, LLC, FOUR SEAGATE - EIGHTH FLOOR, TOLEDO, OH, 43604, US

(73) Assignee: FRAUNHOFER-GESELLSCHAFT ZUR FOERDERUNG DER ANGEWANDTEN FORSCHUNG E.V., MUNICH (DE)

(21) Appl. No.: 12/451,192

(22) PCT Filed: May 14, 2008
(86) PCT No.: PCT/EP2008/003876

§ 371 Date: Apr. 13, 2010

(30) Foreign Application Priority Data
May 14, 2007 (EP) 07009630.0

(51) Int. Cl. H01L 35/00; H01L 29/16; H01L 21/302; H01L 31/18

(52) U.S. Cl. 136/206; 257/616; 438/758; 438/54; 438/93; 257/E29.082; 257/E21.214

(57) ABSTRACT

The invention relates to a semiconductor component which contains one semiconductor layer containing germanium. On the rear-side, i.e. on the side orientated away from the incident light, the semiconductor layer has at least one layer containing silicon carbide which serves, on the one hand, for the reflection of radiation and also as rear-side passivation or as diffusion barrier. A method for the production of semiconductor components of this type is likewise described. The semiconductor components according to the invention are used in particular as thermophotovoltaic cells or multiple solar cells based on germanium.

The invention relates to a semiconductor component which contains at least one semiconductor layer containing germanium. On the rear-side, i.e. on the side orientated away from the incident light, the semiconductor layer has at least one layer containing silicon carbide, which serves, on the one hand, for the reflection of radiation and also as rear-side passivation or as diffusion barrier. A method for the production of semiconductor components of this type is likewise described. The semiconductor components according to the invention are used in particular as thermophotovoltaic cells or multiple solar cells based on germanium.

In thermophotovoltaics, photovoltaic cells are used to convert the radiation of an emitter at a typical temperature of 1000 to 1500° C. into electrical current. There can be used as heat source in such a system conventional energy sources, such as natural gas, or regenerative sources, such as concentrated sunlight. Because of the emitter temperatures which are low compared to the sun, cells with a lower band gap energy are used in thermophotovoltaics. Examples are photovoltaic cells made of gallium antimonide, gallium indium arsenide antimonide or germanium. Germanium is a particularly interesting material for thermophotovoltaics because of the low costs and ready availability.

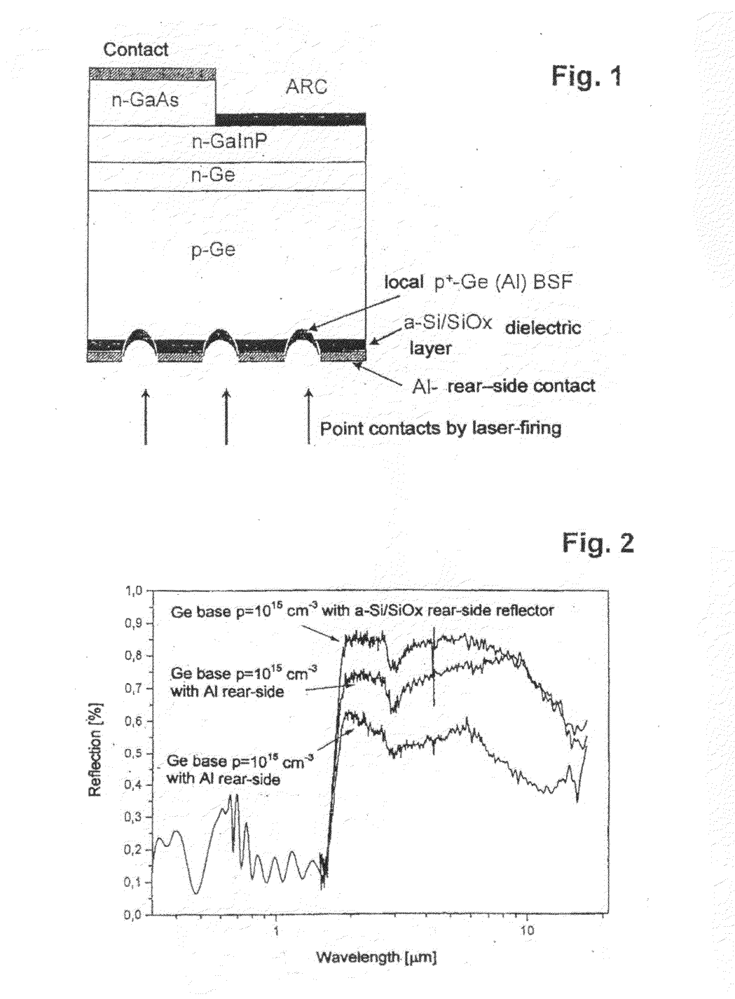

A thermovoltaic cell based on germanium with a rear-side passivation made of amorphous silicon (EP 1 475 844 A2) and a rear-side reflector made of amorphous silicon (a-Si) and SiOₓ is known from the state of the art (Fernandez, J., et al., Back-Surface Optimization of Germanium TPV Cells, In Proc. of 7^{th} World TPV Conference, 2006, El Escorial, Spain). This cell has a rear-side contact made of aluminium which is driven locally with a laser through the dielectric layers. The cell described here and the use thereof is represented schematically in FIG. 1. FIG. 2 shows a reflection spectrum of this thermophotovoltaic cell. It can be detected herefrom that the highest reflectivity of up to 85% in the long-wave spectral range is achieved with low substrate dopings of p=10¹⁵ cm⁻³ with the dielectric rear-side reflector made of a-Si/SiOₓ. The difference in the refractive index of the materials and also optimal adaptation of the layer thicknesses are crucial for high reflectivity of the rear-side reflector. The refractive index of amorphous silicon is approx. 3.6 to 4.3 (at 633 nm), that of silicon oxide approx. 1.4 (at 633 nm).

U.S. Pat. No. 4,495,262 describes a photosensitive element and an electrophotographic photosensitive element with a photoconductive layer which contains amorphous hydrogenated or fluorinated silicon germanium and an amorphous hydrogenated and/or fluorinated silicon germanium carbide. In addition, the elements have a first amorphous hydrogenated and/or fluorinated silicon carbide layer which is disposed on the photoconductive layer. In addition, they have a second amorphous hydrogenated and/or fluorinated silicon carbide layer which is disposed under the photoconductive layer.

Further solar cells based on germanium are known from the field of multiple solar cells with a plurality of series-connected p-n junctions, as are used in satellites and terrestrial PV concentrator systems.

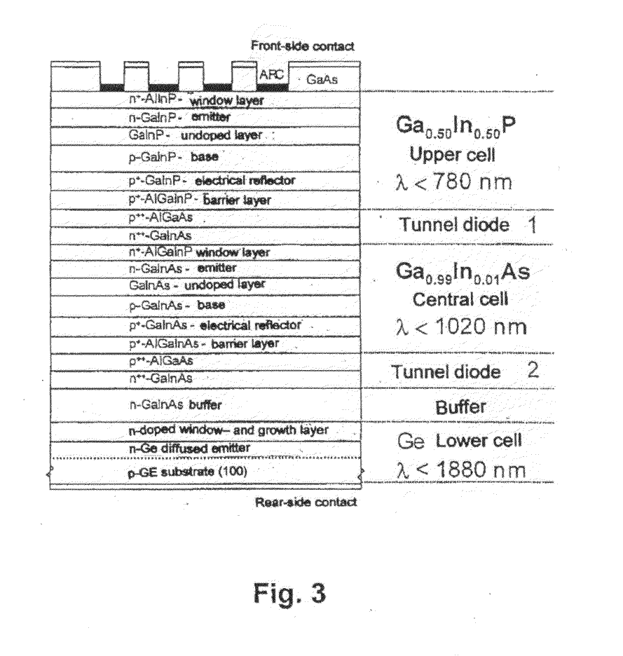

FIG. 3 shows the schematic construction of the layer structure for a III-V multiple solar cell, as is known from the state of the art (Belt et al., “Multi-junction Concentrator Solar Cells” in: Luque et al., Concentrator Photovoltaics, ISBN: 978-3-540-68796-2), with three p-n junctions made of GaInP, GaInAs and germanium. The germanium partial cell is formed by a diffusion of phosphorus or arsenic during growth of the layer structure situated thereabove into the p-n doped germanium substrate. The germanium partial cell typically comprises an emitter with a thickness of 100 to 500 nm. The base thickness corresponds approximately to the thickness of the germanium substrate and, for application in space, is between 130 to 170 μm, for application in terrestrial concentrator systems 150 to 500 μm. The rear-side of the germanium partial cell is covered completely with a metal contact. In this case, the base of the germanium solar cell barely contributes to the current generation. This resides in the fact, on the one hand, that with current space solar cells typically substrate dopings of p>10¹⁷ cm⁻³ are used, the diffusion length for minority charge carriers in this case being fundamentally smaller than the thickness of the base layer of approx. 150 μm. On the other hand, the recombination rate for minority charge carriers at the interface between the germanium and the metal layer is very high.

In the currently used III-V multiple solar cells, the rear-side of the germanium partial cell is not passivated. If it is desired to improve the solar cell further in the future, then a rear-side passivation of the Ge cell is important.

High reflectivity for wavelengths greater than 1850 nm in the case of the space solar cell serves to lower the temperature of the solar cell. These long-wave photons are absorbed typically on the rear-side contact in the current space solar cells and contribute to heating the solar cell. These photons can be emitted from the solar cell and back into space through the reflector made of silicon carbide. Nowadays, this function is fulfilled in part by special coverglasses for space application which are applied on the front-side of the solar cell. In Russell, J., et al., A new UVR/IRR Coverglass for triple junction cells, in Proceedings of the 4^{th} World Conference on Photovoltaic Energy Conversion, 2006, Waikoloa, Hi., USA, it is shown that, by means of an infrared reflector on the coverglass, a reduction in the solar cell temperature in space by 9-13° C. can be expected. This corresponds to an improvement in the absolute efficiency by 0.5 to 0.7%. The reflector on the coverglass described here leads however to also a part of the photons which can be used for the triple solar cell being reflected.

Starting herefrom, it was the object of the present invention to improve existing solar cells based on germanium and to eliminate the described disadvantages of the systems from the state of the art. In particular, semiconductor components of this type are intended hereby to be developed in a simple manner such that, on the one hand, a reflection of photons and also a rear-side passivation of the cell or a diffusion barrier is produced.

This object is achieved by the semiconductor component having the features of claim 1 and the method for production thereof having the features of claim 25. In claims 29 and 30, uses according to the invention are indicated. The further dependent claims reveal advantageous developments.

According to the invention, a semiconductor component is provided which has at least one semiconductor layer having a front-side orientated towards the incident light and a rear-side. The semiconductor layer thereby contains at least 50 at. % germanium. The semiconductor layer thereby has, at least on the rear-side and at least in regions, at least one layer containing silicon carbide.

Silicon carbide thereby confers a large number of advantages which predestine it for use in the semiconductor components according to the invention.

Thus silicon carbide is distinguished by a particularly high temperature stability. Likewise SiC has excellent properties with respect to surface passivation for Ge and Si—Ge. Furthermore, silicon carbide is distinguished in that it represents a good diffusion barrier for impurities from adjacent layers.

This layer containing at least one silicon carbide can thereby have an atomic or electrical function and/or an optical function.

The atomic or electrical function relates to an electrical rear-side passivation or a diffusion barrier in the case of the semiconductor components according to the invention. The layer containing silicon carbide can thereby serve as diffusion barrier for metals and impurities from layers which are situated below the solar cell. A further atomic or electrical function relates to the possibility that the layer containing silicon carbide serves as source for hydrogen or dopants.

The optical function of the layer containing silicon carbide concerns the reflection of photons with an energy close to or less than the band gap energy of the solar cell material. As a result, the path for light close to the band edge with a low absorption by the solar cell material can be approximately doubled. This is advantageous in particular for thin solar cells. In addition, long-wave infrared radiation with an energy less than the band gap of the solar cell can be reflected out of the cell. As a result, heating of the cell due to the absorption of this radiation in the rear-side contact is avoided. This is important in particular for solar cells in space or for thermophotovoltaics.

The layer containing at least one silicon carbide preferably represents a reflector for radiation with a wavelength >1600 nm. The silicon carbide layer(s) thereby have a refractive index in the range of 1.6 to 3.6. A preferred variant provides that the semiconductor component has a plurality of layers containing silicon carbide with different refractive indices. In this case, the layer system comprising layers containing silicon carbide can then act as Bragg reflector.

Preferably, the at least one layer containing silicon carbide has a thickness of 100 to 500 nm. It thereby preferably comprises amorphous silicon carbide or essentially contains amorphous silicon carbide.

The carbon content of the silicon carbide layer or of the layer essentially comprising silicon and carbon is preferably in the range of 5 to 95 at. %. In the case of a carbon content of the silicon carbide layer or of the layer essentially comprising silicon and carbon of 5 at. %, the refractive index of this layer is approx. 3.6, with a carbon content of the silicon carbide layer of 95 at. % at approx. 1.6.

Furthermore, it is preferred that the at least one layer containing silicon carbide is electrically conductive.

In a further advantageous embodiment, the at least one layer containing silicon carbide can be doped. There are possible here as dopants, for example phosphorus, boron or nitrogen.

The semiconductor layer preferably has a thickness of ≧100 μm and <700 μm.

The semiconductor layer thereby comprises preferably germanium or SiₓGe₁₋ₓ with 0<x<0.5.

A further preferred embodiment provides that a dielectric layer is applied at least in regions on the side, orientated away from the semiconductor layer, of the at least one layer containing silicon carbide. There are possible here as dielectric materials, for example silicon oxide, silicon nitride, magnesium fluoride, tantalum oxide or mixtures hereof.

Furthermore, an electrically contacting layer can be applied at least in regions on the side, orientated away from the semiconductor layer, of the at least one layer containing silicon carbide or of the dielectric layer, said electrically contacting layer producing the electrical contact to the semiconductor layer. There are possible here as contacting materials, in particular aluminium, gold, silver, palladium, titanium, nickel or alloys hereof. The electrically contacting layer is thereby in direct electrical contact in regions with the semiconductor layer. This can be achieved for example by laser-fired or photolithographically defined point contacts. However, it is also likewise possible to use an electrically conductive silicon carbide layer, as a result of which the described point contacts can then be dispensed with.

The semiconductor component is preferably a thermophotovoltaic cell. In this case, the layer containing silicon carbide fulfils essentially three functions:
1. Reflection of wavelengths between 1600 to 1850 nm in order to increase the absorption of these photons in the germanium cell. Germanium has a band gap energy of 0.67 eV and accordingly absorbs photons with a wavelength of less than 1850 nm. In the wavelength range between 1600 to 1850 nm, germanium is an indirect semiconductor with low absorption. Due to the reflection of the photons in this wavelength range back into the germanium cell, the absorption probability is increased.
2. Reflection of wavelengths greater than 1850 nm back to the radiation emitter in order to recycle these photons. The long-wave light can thus be used to keep the emitter at its high temperature. Otherwise, these photons would be absorbed in the rear-side contact of the germanium cell and contribute there to undesired heating of the cell.
3. Rear-side passivation of the germanium cell. As a result of a silicon carbide layer on the rear-side of the germanium cell structure, minority charge carriers can be reflected at this boundary layer. The surface recombination can be significantly improved. As a result, higher efficiencies for the conversion of the radiation into electrical energy can be achieved.

A further preferred variant provides that the semiconductor component is a III-V multiple solar cell based on germanium.

As a result of the layer containing silicon carbide according to the invention, which is disposed on the rear-side of this multiple solar cell, the long-wave sunlight can be reflected out from the solar cell and hence the operating temperature of the solar cell can be reduced. Furthermore, the absorption probability of these photons in the germanium cell can be increased by a reflection of wavelengths between 1600 to 1850 nm back into the germanium cell.

It was established furthermore that the layer containing silicon carbide is outstandingly suitable for rear-side passivation of these multiple solar cells. This means that a layer made of silicon carbide on the rear-side of these solar cells reduces the recombination rate for minority charge carriers. In the case of a Ge wafer with 500 μm thickness and p=2*10¹⁵ cm⁻³, the effective lifespan of 15 to 20 μs without passivation is increased to 130 to 200 μs after deposition of a silicon carbide layer with a thickness of 100 nm on both sides of the substrate.

According to the invention, a method for the production of a semiconductor component is likewise provided, as was described previously, in which a wafer containing germanium is introduced into a reaction chamber and, by means of plasma-enhanced chemical vapour deposition (PECVD), thermal CVD (RTCVD) or sputtering, at least one layer containing silicon carbide is deposited.

Preferably a plasma cleaning of the surface of the substrate is effected before the deposition.

There are used as process gases, preferably methane (CH₄) and silane (SiH₄). The stoichiometry of the layers and hence the function thereof can thereby be adjusted via the gas flows of these two process gases.

The described semiconductor components are used both as thermovoltaic cells and as III-V multiple solar cells.

The subject according to the invention is intended to be explained in more detail with reference to the subsequent Figures, without wishing to restrict said subject to the special embodiments shown here.

FIG. 1 shows, with reference to a schematic representation, the construction of a germanium thermophotovoltaic cell,

FIG. 2 shows a reflection spectrum of a germanium thermophotovoltaic cell according to FIG. 1,

FIG. 3 shows, with reference to a schematic representation, the construction of a triple solar cell according to the state of the art,

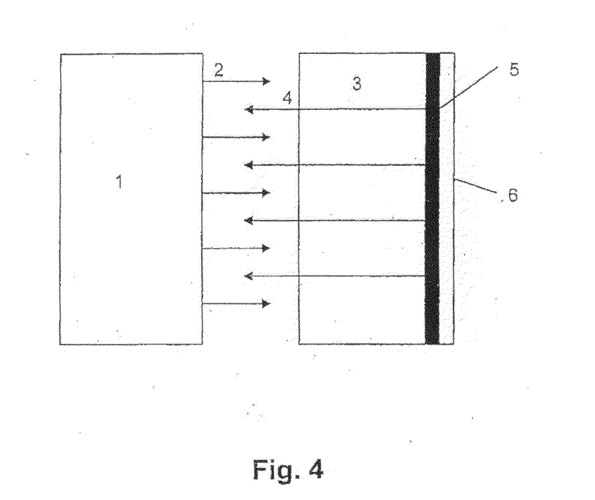

FIG. 4 shows the use of a semiconductor component according to the invention in the form of a germanium thermophotovoltaic cell in a thermophotovoltaic system,

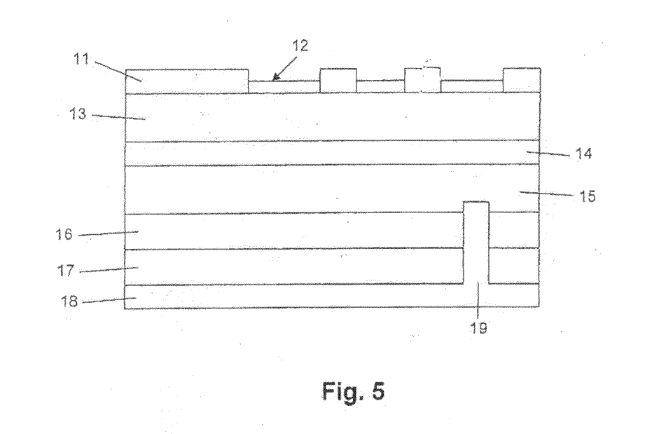

FIG. 5 shows, with reference to a schematic representation, a variant of a semiconductor component according to the invention in the form of a germanium thermophotovoltaic cell,

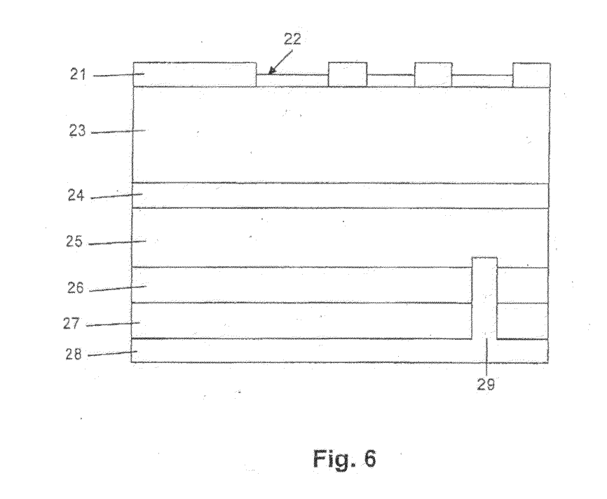

FIG. 6 shows the schematic construction of a III-V multiple cell structure according to the invention.

In FIG. 4, the optical function of the semiconductor component according to the invention is intended to be clarified. The emitter 1 radiates black-body radiation 2 with a temperature of 1000 to 1500° C. The germanium thermophotovoltaic cell 3 converts the part of the spectrum with wavelengths up to 1850 nm into electrical current. The longer-wave light is for the most part absorbed in the rear-side contact 6 and leads to undesired heating of the cell. Therefore, according to the present invention, a layer 5 containing silicon carbide is contained as rear-side reflector between photovoltaic cell 3 and rear-side contact 6. This rear-side reflector reflects light 4 with a wavelength greater than 1600 nm.

FIG. 5 shows in detail the construction of a germanium thermophotovoltaic cell according to the invention. A front-side contact 11 which can be interrupted by regions with an antireflection coating 12 is disposed on the surface orientated towards the light. Below these layers, a window layer or front-side passivation 13 is disposed. Below the latter, the substrate comprising a germanium emitter 14 and a germanium base 15 is disposed in turn. The now following layer 16 containing silicon carbide, which serves in the present case as rear-side passivation, is essential to the invention. On the rear-side thereof, a reflector comprising a plurality of layers with a different refractive index is disposed, which can comprise, for example silicon carbide, silicon oxide or silicon nitride layers. On the rear-side there is located finally a contacting 18 which has for example laser-fired or photolithographically defined point contacts 19. In the case of a conductive silicon carbide layer, these point contacts can also be dispensed with.

FIG. 6 shows the construction of a III-V multiple solar cell structure according to the invention. The latter has a front-side contact 21 which is interrupted in regions by an antireflection coating 22. On the side orientated away from the light there is connected thereto a III-V multiple solar cell structure 23. Below the latter, a germanium partial cell with germanium emitter 24 and germanium base 25 is disposed. On the rear-side thereof, a layer 26 containing silicon carbide is disposed in turn for rear-side passivation. The reflector 27 comprising a plurality of layers with a different refractive index can comprise silicon carbide, silicon oxide or silicon nitride. On the rear-side, finally another rear-side contacting 28 made of aluminium is disposed and has a laser-fired or photolithographically defined point contact 29.

1-30. (canceled)

31. A semiconductor component which contains at least one semiconductor layer containing more than 50 at. % germanium, having a front-side orientated towards the incident light and a rear-side, the semiconductor layer having, at least on the rear-side and at least in regions, at least one layer containing silicon carbide.

32. The semiconductor component according to claim 31, wherein the at least one layer containing silicon carbide is a surface passivation layer for the semiconductor layer.

33. The semiconductor component according to claim 31, wherein the at least one layer containing silicon carbide is a reflector for radiation with a wavelength greater than 1600 nm.

34. The semiconductor component according to claim 31, wherein the at least one layer containing silicon carbide has a refractive index in the range of 1.6 to 3.6.

35. The semiconductor component according to claim 31, wherein the semiconductor component has a plurality of layers containing silicon carbide with different refractive indices.

36. The semiconductor component according to claim 35, wherein the layers containing silicon carbide act as Bragg reflector.

37. The semiconductor component according to claim 31, wherein the at least one layer containing silicon carbide has a thickness of 100 to 500 nm.

38. The semiconductor component according to claim 31, wherein the at least one layer containing silicon carbide comprises amorphous silicon carbide or essentially contains the latter.

39. The semiconductor component according to claim 31, wherein the at least one layer containing silicon carbide is electrically conductive.

40. The semiconductor component according to claim 31, wherein the at least one layer containing silicon carbide is doped with phosphorus, boron and/or nitrogen.

41. The semiconductor component according to claim 31, wherein the semiconductor component has a reflectivity for radiation in the wavelength range of 1800 to 4000 nm of more than 60%.

42. The semiconductor component according to claim 31, wherein the semiconductor component has a reflectivity for radiation in the wavelength range of 1800 to 4000 nm of more than 80%.

43. The semiconductor component according to claim 31, wherein the semiconductor layer has a thickness greater than or equal to 100 μm and less than 700 μm.

44. The semiconductor component according to claim 31, wherein the semiconductor layer contains at least 90 at. % germanium.

45. The semiconductor component according to claim 31, wherein the semiconductor layer comprises SiₓGe₁₋ₓ with 0<x<0.5.

46. The semiconductor component according to claim 31, wherein the at least one layer containing silicon carbide is disposed in a planar manner on the semiconductor layer.

47. The semiconductor component according to claim 31, wherein a dielectric layer is disposed at least in regions on the side, orientated away from the semiconductor layer, of the at least one layer containing silicon carbide.

48. The semiconductor component according to claim 47, wherein the dielectric layer comprises silicon oxide, silicon nitride, magnesium fluoride, tantalum oxide or mixtures hereof or essentially contains these.

49. The semiconductor component according to claim 31, wherein an electrically contacting layer is applied at least in regions on the side, orientated away from the semiconductor layer, of the at least one layer containing silicon carbide or the dielectric layer, said electrically contacting layer producing the electrical contact to the semiconductor layer.

50. The semiconductor component according to claim 49, wherein the electrically contacting layer comprises aluminium, gold, silver, palladium, titanium, nickel or alloys hereof or essentially contains them.

51. The semiconductor component according to claim 49, wherein the electrically contacting layer is in direct electrical contact in regions with the semiconductor layer.

52. The semiconductor component according to claim 31, wherein the semiconductor component is a thermophotovoltaic cell.

53. The semiconductor component according to claim 52, wherein the layer containing silicon carbide is disposed on the side of the photovoltaic cell orientated away from light.

54. The semiconductor component according to claim 53, wherein the semiconductor component is a thermophotovoltaic cell for converting the radiation of a thermal emitter with a temperature of 800 to 2000° C. into electrical current.

55. The semiconductor component according to claim 31, wherein the semiconductor component is a III-V multiple solar cell.

56. A method for the production of a semiconductor component according to claim 31, in which a substrate containing germanium is introduced into a reaction chamber and, by means of plasma-enhanced chemical vapor deposition (PECVD), thermal CVD (RTCVD) or sputtering, at least one layer containing silicon carbide is deposited.

57. The method according to claim 56, wherein plasma cleaning of the surface of the substrate is effected before the deposition.

58. The method according to claim 56, wherein methane (CH₄) and silane (SiH₄) are used as process gases.

59. The method according to claim 56, wherein the stoichiometry of the layers and hence the function thereof is adjusted via the gas flows of the process gases CH₄ and SiH₄.

60. A method of forming a thermophotovoltaic cell utilizing the semiconductor component according to claim 31.

61. A method of forming a III-V multiple solar cell utilizing the semiconductor component according to claim 31.
